(19) United States
(12) Patent Application Publication
(10) Pub. No.: US 2025/0300092 A1
(43) Pub. Date: Sep. 25, 2025

(54) SEMICONDUCTOR DEVICE

(71) Applicant: Kioxia Corporation, Tokyo (JP)

(72) Inventor: Satoru TAKAKU, Yokohama (JP)

(73) Assignee: Kioxia Corporation, Tokyo (JP)

(21) Appl. No.: 18/973,629

(22) Filed: Dec. 9, 2024

(30) Foreign Application Priority Data
Mar. 19, 2024 (JP) 2024-043542

(51) Int. Cl. H01L 23/00; H01L 23/498

(52) U.S. Cl. CPC H01L 23/562; H01L 23/49816; H01L 23/49822; H01L 23/49838; H01L 24/32; H01L 24/48; H01L 24/73; H01L 2224/32225; H01L 2224/48225; H01L 2224/73265; H01L 2924/14511; H01L 2924/3512

(57) ABSTRACT

In one embodiment, a semiconductor device includes a substrate including one or more wiring layers, a first insulator provided on an upper face of a first wiring layer that is an uppermost layer among the one or more wiring layers, and a second insulator provided on a lower face of a second wiring layer that is a lowermost layer among the one or more wiring layers. The device further includes a semiconductor chip provided on the substrate. The first or second wiring layer includes a first wiring and a second wiring that extend from an opening provided in the first or second insulator, and a third wiring that is provided at a position facing the opening between the first wiring and the second wiring.

### CROSS REFERENCE TO RELATED APPLICATION

This application is based upon and claims the benefit of priority from the prior Japanese Patent Application No. 2024-043542, filed on Mar. 19, 2024, the entire contents of which are incorporated herein by reference.

### FIELD

Embodiments described herein relate to a semiconductor device.

### BACKGROUND

In a semiconductor package, occurrence of a crack may be a problem. For example, the crack potentially propagates from an etch-back (EB) opening provided in a solder resist (SR) layer into the interior of the SR layer, causing a defect in the semiconductor package.

### BRIEF DESCRIPTION OF THE DRAWINGS

FIG. 1 is a cross-sectional view illustrating a structure of a semiconductor device of a first embodiment;

FIG. 2 is a cross-sectional view for describing cracks in the semiconductor device of the first embodiment;

FIG. 3 is a plan view illustrating a structure of a semiconductor device of a comparative example of the first embodiment;

FIGS. 4A and 4B are plan views for describing an EB opening in the semiconductor device of the comparative example of the first embodiment;

FIGS. 5A and 5B are plan views for describing cracks in the semiconductor device of the comparative example of the first embodiment;

FIG. 6 is another plan view for describing cracks in the semiconductor device of the comparative example of the first embodiment;

FIG. 7 is a plan view illustrating the structure of the semiconductor device of the first embodiment;

FIGS. 8A to 8D are plan views illustrating various examples of a dummy wiring in the semiconductor device of the first embodiment;

FIGS. 9A and 9B are plan views illustrating EB openings of first and second modifications of the first embodiment;

FIGS. 10A and 10B are plan views illustrating EB openings of third and fourth modifications of the first embodiment; and

FIG. 11 is a cross-sectional view illustrating a structure of a semiconductor device of a second embodiment.

### DETAILED DESCRIPTION

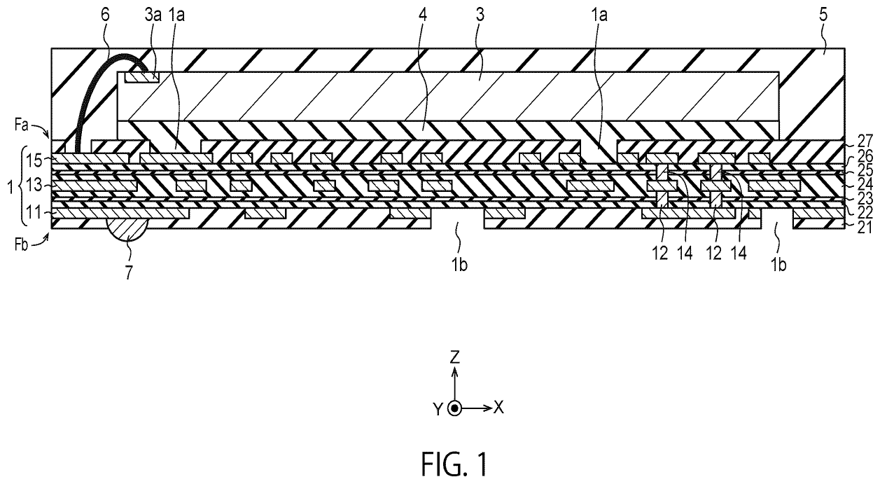

Embodiments will now be explained with reference to the accompanying drawings. In FIGS. 1 to 11, identical components are denoted by the same reference sign, and duplicate description thereof is omitted.

In one embodiment, a semiconductor device includes a substrate including one or more wiring layers, a first insulator provided on an upper face of a first wiring layer that is an uppermost layer among the one or more wiring layers, and a second insulator provided on a lower face of a second wiring layer that is a lowermost layer among the one or more wiring layers. The device further includes a semiconductor chip provided on the substrate. The first or second wiring layer includes a first wiring and a second wiring that extend from an opening provided in the first or second insulator, and a third wiring that is provided at a position facing the opening between the first wiring and the second wiring.

### First Embodiment

FIG. 1 is a cross-sectional view illustrating a structure of a semiconductor device of a first embodiment. In FIG. 1, the semiconductor device of the present embodiment has a form of a semiconductor package. The semiconductor device of the present embodiment includes a substrate 1, a semiconductor chip 3, a resin layer 4, a resin layer 5, a plurality of bonding wires 6, and a plurality of solder balls 7. One of the bonding wires 6 and one of the solder balls 7 are included in a section illustrated in FIG. 1, whereas the other bonding wires 6 and the other solder balls 7 are included in other sections.

The substrate 1 includes a wiring layer 11, a plurality of via plugs 12, a wiring layer 13, a plurality of via plugs 14, a wiring layer 15, and resin layers 21 to 27. Two of the via plugs 12 and two of the via plugs 14 are included in the section illustrated in FIG. 1, whereas the other via plugs 12 and 14 are included in other sections. The wiring layers 11, 13, and 15 are an example of one or more wiring layers. The wiring layer 15 is an example of a first wiring layer, and the wiring layer 11 is an example of a second wiring layer. The resin layer 27 is an example of a first insulator, and the resin layer 21 is an example of a second insulator.

The substrate 1 is, for example, a wiring substrate such as a printed circuit board. FIG. 1 illustrates an upper face Fa of the substrate 1 and a lower face Fb of the substrate 1. FIG. 1 also illustrates an X direction and a Y direction that are parallel to the upper face Fa and the lower face Fb of the substrate 1 and orthogonal to each other, and a Z direction orthogonal to the upper face Fa and the lower face Fb of the substrate 1. The X direction, the Y direction and the Z direction intersect each other.

The wiring layers 11, 13, and 15 form a multi-layer wiring structure in the substrate 1. The wiring layer 11 is lowermost among the wiring layers 11, 13, and 15. The wiring layer 15 is uppermost among the wiring layers 11, 13, and 15. The wiring layer 13 is provided between the wiring layers 11 and 15, and positioned above the wiring layer 11 and below the wiring layer 15. Each of the wiring layers 11, 13, and 15 is, for example, a metal layer including a copper (Cu) layer. Each of the wiring layers 11, 13, and 15 includes a plurality of wirings. The multi-layer wiring structure in the substrate 1 may include four or more wiring layers or may include only one or two wiring layers.

Each via plug 12 is provided between the wiring layers 11 and 13 and electrically connects the wiring layers 11 and 13. Each via plug 14 is provided between the wiring layers 13 and 15 and electrically connects the wiring layers 13 and 15. Each of the via plugs 12 and 14 is, for example, a metal layer including a Cu layer.

The resin layers 21 to 27 are sequentially stacked from the lower face Fb of the substrate 1 to the upper face Fa. The resin layer 21 is provided on the lower face of the wiring layer 11 and forms the lower face Fb of the substrate 1. The resin layers 22 and 23 are sequentially provided between the upper faces of the resin layer 21 and the wiring layer 11 and a lower face of the resin layer 24. The resin layer 24 is provided to enclose the wiring layer 13. The resin layers 25 and 26 are sequentially provided between the upper face of the resin layer 24 and the lower faces of the resin layer 27 and the wiring layer 15. The resin layer 27 is provided on the upper face of the wiring layer 15 and forms the upper face Fa of the substrate 1.

Each of the resin layers 21 to 27 is, for example, an insulator. More specifically, the resin layers 21 and 27 are, for example, solder resist (SR) layers. The resin layers 22, 24, and 26 are, for example, prepreg layers. The resin layers 23 and 25 are, for example, glass cloth layers.

FIG. 1 also illustrates a plurality of etch-back (EB) openings 1a and 1b provided in the substrate 1. The EB openings 1b are provided in the resin layer 21 and the wiring layer 11 at the lower face Fb of the substrate 1. The EB openings 1a are provided in the resin layer 27 and the wiring layer 15 at the upper face Fa of the substrate 1. The left EB opening 1a illustrated in FIG. 1 is not provided in the wiring layer 15 in FIG. 1 but is provided in the wiring layer 15 at another section. The EB openings 1a and 1b of the present embodiment are formed when the resin layers 27 and 21 and the wiring layers 15 and 11, respectively, are processed by etching back. Further details of the EB openings 1a and 1b of the present embodiment will be described later.

The semiconductor chip 3 is provided on the substrate 1 via the resin layer 4. The semiconductor chip 3 is, for example, a memory chip including a three-dimensional NAND memory. The semiconductor device of the present embodiment may include two or more semiconductor chips.

The resin layers 4 and 5 are provided on the substrate 1. More specifically, the resin layer 4 is provided between the substrate 1 and the semiconductor chip 3 and in the EB openings 1a of the substrate 1. The resin layer 5 is provided on the substrate 1 to cover the semiconductor chip 3. The resin layer 4 is, for example, a bonding layer. The resin layer 5 is, for example, an epoxy resin layer.

Each bonding wire 6 electrically connects the corresponding semiconductor chip 3 and the wiring layer 15. The bonding wire 6 illustrated in FIG. 1 electrically connects a bonding pad 3a provided on the upper face of the semiconductor chip 3 and a wiring (bonding pad) in the wiring layer 15. In FIG. 1, the resin layer 27 has an opening for joining this wiring and the bonding wires 6.

The solder balls 7 are provided on the lower face of the wiring layer 11 and electrically connected to the wiring layer 11. The solder ball 7 illustrated in FIG. 1 is provided on the lower face of a wiring (external connection pad) in the wiring layer 11. In FIG. 1, the resin layer 21 has an opening for joining this wiring and the solder balls 7. The wiring is electrically connectable to a device outside the semiconductor device of the present embodiment through the solder ball 7. The wiring may be electrically connected to a device outside the semiconductor device of the present embodiment through a member (for example, metal bump) other than the solder ball 7.

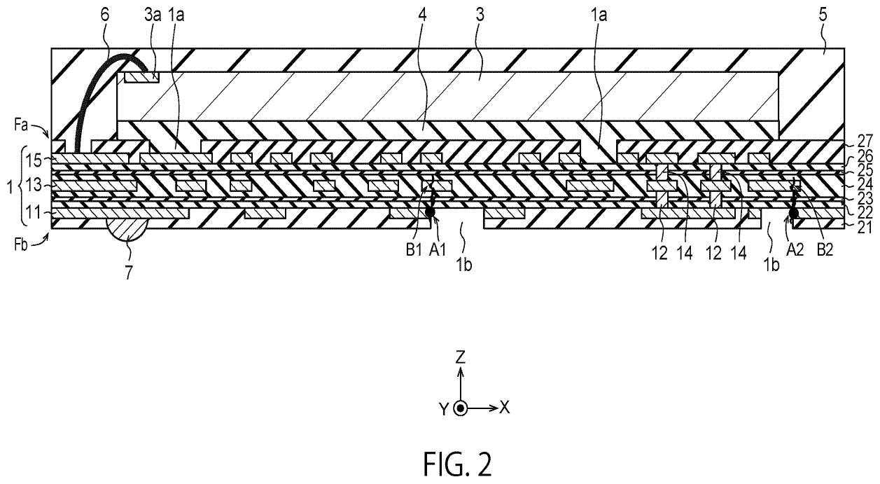

FIG. 2 is a cross-sectional view for describing cracks in the semiconductor device of the first embodiment.

FIG. 2 illustrates an example of various kinds of cracks that may occur in the semiconductor device of the present embodiment. In FIG. 2, cracks B1 and B2 originate from starting points A1 and A2, respectively. Specifically, the crack B1 originates from the starting point A1 on the side face of one EB opening 1b and propagates in the substrate 1, and the crack B2 originates from the starting point A2 on the side face of another EB opening 1b and propagates in the substrate 1. In FIG. 2, 15 the cracks B1 and B2 cause fractures in the substrate 1.

In a temperature cycling test (TCT) of the semiconductor device of the present embodiment, the resin layers 27 and 21 are prone to cracking due to thermal stress near the EB openings 1a and 1b. As a result, cracks occur in the substrate 1, and the wiring layers 11, 13, and 15 in the substrate 1 are potentially fractured due to cracks. When the wiring layers 11, 13, and 15 are fractured due to cracks, defects potentially occur to the semiconductor device of the present embodiment. Cracks are likely to occur at, for example, the interface between the wiring layer 11 and the resin layer 21 and the interface between the wiring layer 15 and the resin layer 27 and likely to propagate along the wiring layers 11 and 15.

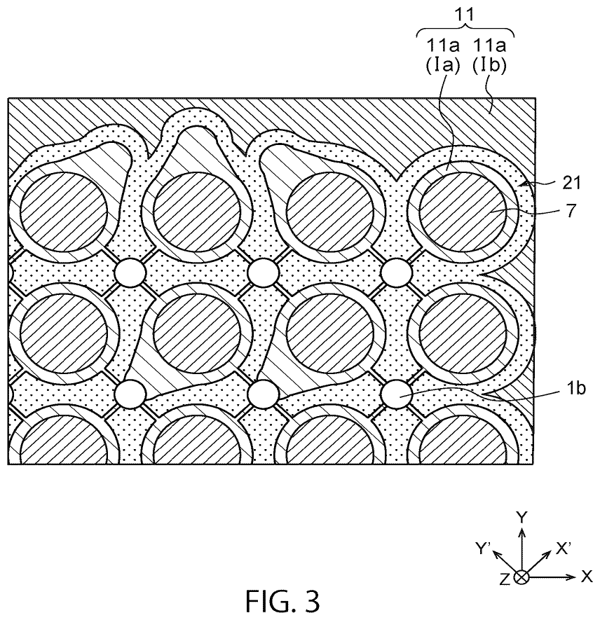

A semiconductor device of a comparative example of the first embodiment will be described below with reference to FIGS. 3 to 5. The semiconductor device of the present comparative example has a structure generally the same as the semiconductor device of the first embodiment, and the structure illustrated in FIG. 1 is generally common to the first embodiment and the present comparative example. Thus, in description of the semiconductor device of the present comparative example, the same reference signs as those used in description of the semiconductor device of the first embodiment are used and FIG. 1 is referred to as appropriate.

FIG. 3 is a plan view illustrating the structure of the semiconductor device of the comparative example of the first embodiment.

FIG. 3 corresponds to a plan view of the lower face Fb of the substrate 1 illustrated in FIG. 1 when viewed upward. FIG. 3 illustrates the wiring layer 11, the resin layer 21 (hatched with dots), a plurality of solder balls 7, and a plurality of EB openings 1b. However, to illustrate the shape of the wiring layer 11, FIG. 3 omits illustration of the resin layer 21 covering the lower face of the wiring layer 11 and illustrates only the resin layer 21 provided in the wiring layer 11. In other words, FIG. 3 illustrates an XY section of the semiconductor device of the present comparative example at the height of the lower face of the wiring layer 11.

The wiring layer 11 of the present comparative example includes a plurality of wirings 11a separated from each other. In FIG. 3, the wirings 11a include 12 wirings 11a having island shapes (hereinafter also referred to as “island-shaped wirings 11a”) as illustrated with reference sign Ia, and one wiring 11a provided around the island-shaped wirings 11a (hereinafter also referred to as a “surrounding wiring 11a”) as illustrated with reference sign Ib. The island-shaped wirings 11a are used as external connection pads electrically connected to the solder balls 7. In FIG. 3, the solder balls 7 are provided on the lower faces of the island-shaped wirings 11a. The lower face of each island-shaped wiring 11a includes a portion covered by the corresponding solder ball 7 and a portion positioned around the solder ball 7. FIG. 3 illustrates the portions of the lower face of each island-shaped wiring 11a, which are positioned around the solder balls 7. Each island-shaped wiring 11a includes one or more linear

portions having linear shapes as illustrated in FIG. 3. Each linear portion extends to either EB opening 1b. Similarly, the surrounding wiring 11a includes one or more linear portions extending to one or more EB openings 1b outside the region illustrated in FIG. 3. The wirings 11a (the island-shaped wirings 11a and the surrounding wiring 11a) of the present comparative example are coupled to one another through these linear portions before the EB openings 1b are formed, but are separated from one another after the EB openings 1b are formed. The reason the wirings 11a are coupled to one another before the EB openings 1b are formed is to provide plating to the wirings 11a (in other words, the wiring layer 11).

The plating is formed of, for example, a gold (Au) layer. The reason the wirings 11a are separated from one another after the EB openings 1b are formed is to eliminate short-circuit of the wirings 11a.

In FIG. 3, each EB opening 1b is disposed among four island-shaped wirings 11a. These island-shaped wirings 11a are coupled to one another before this EB opening 1b is formed, but are separated from one another after the EB opening 1b is formed. Like the two central island-shaped wirings 11a and their two lower-left EB openings 1b illustrated in FIG. 3, each island-shaped wiring 11a may extend to an EB opening 1b in a form other than a linear portion. Each opening 1b of the present comparative example has a circular shape in a plan view as illustrated in FIG. 3.

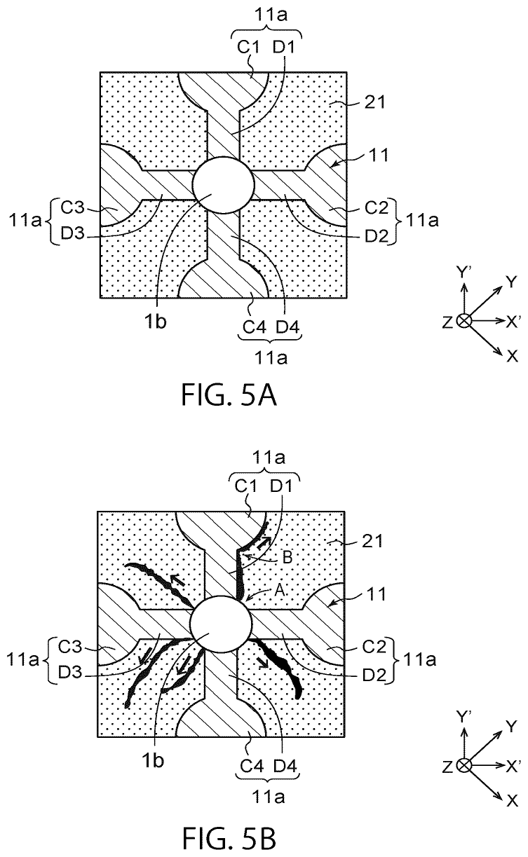

FIG. 3 illustrates, in addition to the X, Y, and Z directions, an X′ direction and a Y′ direction that are parallel to the upper face Fa and the lower face Fb of the substrate 1 and orthogonal to each other. The X′ direction is the 45° direction on the XY plane. The Y′ direction is the 135° direction on the XY plane. In FIG. 3, each linear portion extends in parallel to the X′ direction or the Y′ direction. The X′ and Y′ directions are used in description of FIGS. 5 to 10, for example.

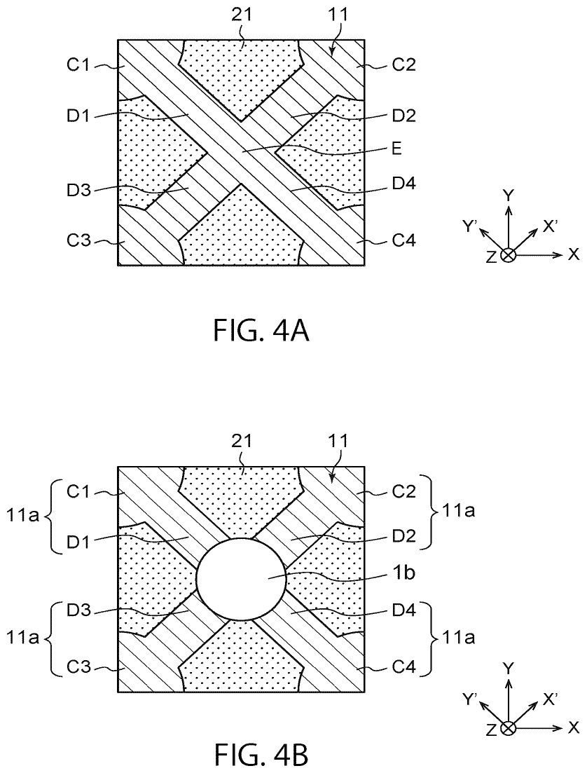

FIGS. 4A and 4B are plan views for describing an EB opening in the semiconductor device of the comparative example of the first embodiment.

The wiring layer 11 illustrated in FIG. 4A includes four planar portions C1 to C4 having planar shapes, four linear portions D1 to D4 having linear shapes, and one coupling portion E. The linear portions D1 to D4 extend from the planar portions C1 to C4, respectively, to the coupling portion E and are coupled to one another at the coupling portion E.

FIG. 4A illustrates the wiring layer 11 before the EB opening 1b is formed, and FIG. 4B illustrates the wiring layer 11 after the EB opening 1b is formed. In FIG. 4B, the EB opening 1b is formed at the coupling portion E. As a result, the wiring layer 11 is processed in a shape including a wiring 11a with the planar portion C1 and the linear portion D1, a wiring 11a with the planar portion C2 and the linear portion D2, a wiring 11a with the planar portion C3 and the linear portion D3, and a wiring 11a with the planar portion C4 and the linear portion D4. These wirings 11a are separated from one another by the EB opening 1b.

These wirings 11a correspond to the island-shaped wirings 11a illustrated in FIG. 3. The planar portions C1 to C4 of these wirings 11a correspond to the above-described external connection pads. Accordingly, the solder balls 7 (not illustrated) are provided on the lower faces of the planar portions C1 to C4.

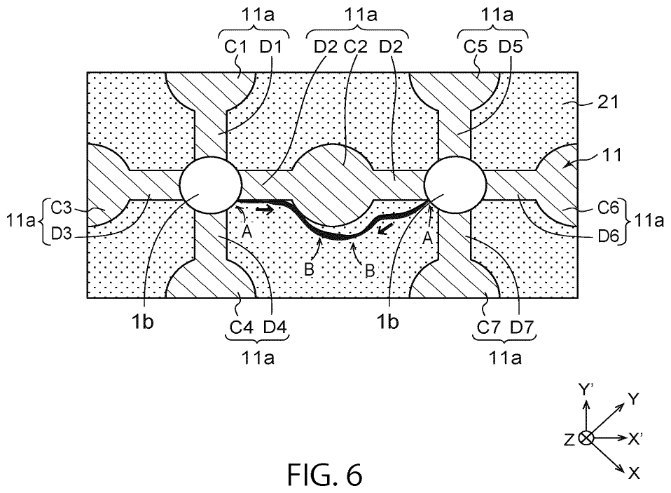

FIGS. 5A, 5B and 6 are plan views for describing cracks in the semiconductor device of the comparative example of the first embodiment.

FIG. 5A illustrates the same wiring layer 11 as the wiring layer 11 in FIG. 4B. However, the plan view of FIG. 5A is a 45° rotation of the plan view of FIG. 4B such that the X′ direction is horizontal and the Y′ direction is vertical to facilitate description of cracks.

FIG. 5A illustrates the wiring layer 11 before cracks occur, and FIG. 5B illustrates the wiring layer 11 after cracks occur. FIG. 5B illustrates a plurality of cracks B originating from a plurality of starting points A. The cracks B originate from the starting points A on the side face of the EB opening 1b and the starting points A on the linear portions D1 to D4 near the EB opening 1b. Arrows illustrated in FIG. 5B represent directions in which the cracks B propagate.

As described above, the cracks B are likely to originate from the starting points A near the EB opening 1b. In FIG. 5B, the cracks B originating from the starting points A near the EB opening 1b propagate in the resin layer 21 between the linear portion D1 and the linear portion D2, the resin layer 21 between the linear portion D1 and the linear portion D3, the resin layer 21 between the linear portion D3 and the linear portion D4, and the resin layer 21 between the linear portion D2 and the linear portion D4. The cracks B propagate in in-plane directions of the XY plane in FIG. 5B, but propagate in the Z direction as well. When the cracks B propagate in in-plane directions of the XY plane, the cracks B are likely to propagate in the Z direction as well.

While FIGS. 5A and 5B illustrate the planar portions C1 to C4 and the linear portions D1 to D4 near one EB opening 1b, FIG. 6 illustrates planar portions C1 to C7 and linear portions D1 to D7 near two EB openings 1b. For example, as illustrated in FIG. 6, when cracks B originate from the EB openings 1b and propagate in in-plane directions of the XY plane, the adjacent cracks B near the EB openings 1b potentially are connected to each other and broadly propagate. As a result, when the wiring layer 11 is fractured by the cracks B, defects potentially occurs to the semiconductor device of the present comparative example. For example, when the wirings 11a used as signal lines are fractured by the cracks B, necessary signals potentially stop propagating in the semiconductor device. Similarly, when the cracks B propagate in the Z direction, wirings in the wiring layers 13 and 15 used as signal lines are potentially fractured by the cracks B (details will be described in a second embodiment).

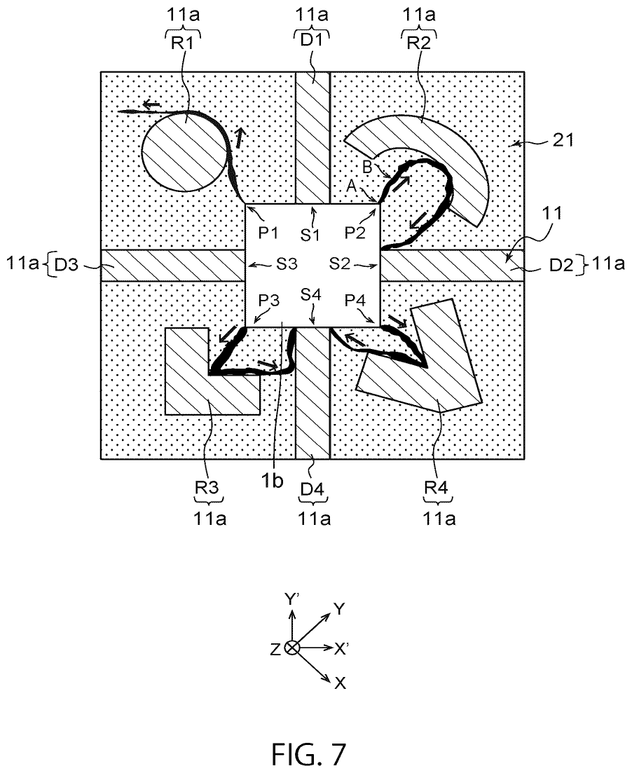

The contents of the above description with reference to FIGS. 3 to 6 are applicable not only to the EB openings 1b, the wiring layer 11, and the resin layer 21 but also to the EB openings 1a, the wiring layer 15, and the resin layer 27 in a similar manner. This is the same for FIGS. 7 to 11 to be described later.

FIG. 7 is a plan view illustrating the structure of the semiconductor device of the first embodiment.

FIG. 7 is a plan view corresponding to FIG. 5B. However, the EB opening 1b illustrated in FIG. 7 has a rectangular (for example, square) shape in a plan view. FIG. 7 illustrates four side faces S1 to S4 of the EB opening 1b and four corners P1 to P4 between the side faces S1 to S4. In the plan view of the EB opening 1b, the side faces S1 to S4 correspond to the four sides of the rectangle, and the corners P1 to P4 correspond to the four corners of the rectangle.

The corners P1 to P4 protrude into the resin layer 21 in a plan view. Through discussions, it was found that cracks B are likely to originate from starting points A at the corners P1 to P4. FIG. 7 illustrates a crack B originating from a starting point A at the corner P1, a crack B originating from a starting point A at the corner P2, a crack B originating from a starting point A at the corner P3, and a crack B originating from a starting point A at the corner P4. At the corners P1 to P4, the cracks B are connected to the EB opening 1b. As illustrated in FIG. 7, the cracks B are likely to propagate along the wirings 11a. The corners P1 to P4 are an example of one or more protrusion portions and an example of first protrusion portions.

The present embodiment makes it possible to control the occurrence positions of cracks B since the EB opening 1b is provided with the corners P1 to P4. For example, since the corner P1 is provided not on the linear portions D1 and D3 but between the linear portions D1 and D3, it is possible to prevent the starting point A of a crack B from occurring on the linear portions D1 and D3, thereby making it easier to prevent the crack B from fracturing the linear portions D1 and D3. In FIG. 7, the corner P1 is provided far from the linear portion D1 and far from the linear portion D3. This is the same for the corners P2 to P4. The corner P2 is provided not on the linear portions D1 and D2 but between the linear portions D1 and D2, the corner P3 is provided not on the linear portions D3 and D4 but between the linear portions D3 and D4, and the corner P4 is provided not on the linear portions D2 and D4 but between the linear portions D2 and D4.

The EB opening 1b illustrated in FIG. 7 has, for example, a square shape in a plan view. Accordingly, the corner P1 has a shape that forms a right angle in a plan view. In other words, the angle between the side faces S1 and S3 in a plan view is 90°. This is the same for the corners P2 to P4. The corners P1 to P4 may each have a shape that forms an acute angle in a plan view or have a shape that forms an obtuse angle in a plan view. However, since an acute-angled corner is more likely to serve as the starting point A of a crack B than an obtuse-angled corner, the corner shape desirably forms an acute angle rather than an obtuse angle.

Each EB opening 1b may have a polygonal (for example, regular polygonal) shape other than a rectangular shape in a plan view. Examples of such polygons include triangles and hexagons. Various examples of the planar shape of each EB opening 1b will be described later.

Similarly to the wiring layer 11 of the comparative example, the wiring layer 11 of the present embodiment includes a wiring 11a including a planar portion C1 and a linear portion D1, a wiring 11a including a planar portion C2 and a linear portion D2, a wiring 11a including a planar portion C3 and a linear portion D3, and a wiring 11a including a planar portion C4 and a linear portion D4. However, FIG. 7 omits illustration of the planar portions C1 to C4. The linear portions D1 to D4 extend from the side faces S1 to S4, respectively, of each EB opening 1b to the planar portions C1 to C4. The linear portions D1 to D4 of the wirings 11a are an example of first and second wirings, and the planar portions C1 to C4 of the wirings 11a are an example of first and second pads.

The wiring layer 11 of the present embodiment also includes a wiring 11a including a portion R1, a wiring 11a including a portion R2, a wiring 11a including a portion R3, and a wiring 11a including a portion R4. The wiring 11a including the portion R1 is provided at a position facing the corner P1 of the EB opening 1b between the linear portions D1 and D3. The wiring 11a including the portion R2 is provided at a position facing the corner P2 of the EB opening 1b between the linear portions D1 and D2. The wiring 11a including the portion R3 is provided at a position facing the corner P3 of the EB opening 1b between the linear portions D3 and D4. The wiring 11a including the portion R4 is provided at a position facing the corner P4 of the EB opening 1b between the linear portions D2 and D4. The wirings 11a including the portions R1 to R4 are an example of third wirings.

The wirings 11a including the portions R1 to R4 are, for example, dummy wirings that do not function as wirings that can control the semiconductor device of the present embodiment. Thus, the wirings 11a including the portions R1 to R4 are not electrically connected to the semiconductor chip 3 nor the solder balls 7 and cannot control the semiconductor chip 3. The wirings 11a including the portions R1 to R4 may be wirings electrically connected to the semiconductor chip 3 or the solder balls 7 but not used to control the semiconductor chip 3. The dummy wirings of the present embodiment may be achieved in the former aspect or the latter aspect. Hereinafter, the wirings 11a including the portions R1 to R4 are also referred to as “dummy wirings 11a” or “dummy wirings R”. In FIG. 7, the dummy wirings R are electrically insulated from the other wirings 11a than the dummy wirings R (such as the wirings 11a including the linear portions D1 to D4) and also electrically insulated from one another.

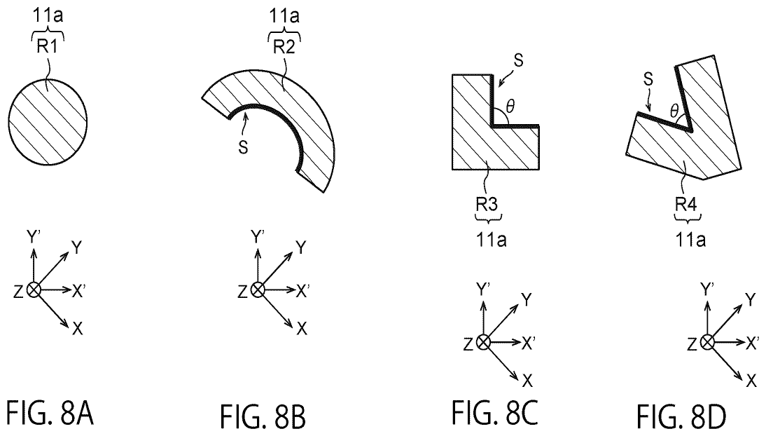

Further details of the dummy wirings 11a will be described below with reference to FIG. 7. In addition, FIGS. 8A to 8D are referred as appropriate in the description. FIGS. 8A to 8D are plan views illustrating various examples of a dummy wiring 11a in the semiconductor device of the first embodiment.

The dummy wiring 11a including the portion R1 has a circular shape in a plan view as illustrated in FIGS. 7 and 8A. Hereinafter, the dummy wiring 11a including the portion R1 is also referred to as a “dummy wiring R1” to distinguish them from the other dummy wirings 11a.

In FIG. 7, the crack B originating from the starting point A at the corner P1 reaches the dummy wiring R1. As a result, the direction in which the crack B propagates changes at the dummy wiring R1. The reason is that the crack B tends to propagate more easily to the resin layer 21 than to the dummy wiring R1. According to the present embodiment, since the dummy wiring R1 is disposed near the corner P1, it is possible to restrict a range in which the crack B propagates near the corner P1 and prevent the crack B from broadly propagating. In other words, the dummy wiring R1 functions as a guide that changes the propagating direction of the crack B.

The dummy wiring 11a including the portion R2 has an arc shape in a plan view as illustrated in FIGS. 7 and 8B. Hereinafter, the dummy wiring 11a including the portion R2 is also referred to as a “dummy wiring R2”.

FIG. 8B illustrates a side face S of the dummy wiring R2 in the negative Y direction with a bold line. The side face S of the dummy wiring R2 faces the corner P2 in a plan view as illustrated in FIG. 7. Specifically, the side face S of the dummy wiring R2 has a curved shape in a plan view and is recessed in the direction departing from the EB opening 1b. In the present embodiment, since the dummy wiring R2 has an arc shape in a plan view, the side face S of the dummy wiring R2 has a shape forming an arc (portion of a circle) in a plan view. The shape of the side face S of the dummy wiring R2 is concave in the positive Y direction in a plan view.

In FIG. 7, the crack B originating from the starting point A at the corner P2 reaches the side face S of the dummy wiring R2 and then returns to the EB opening 1b. The reason is that since the side face S of the dummy wiring R2 is recessed, the crack B having reached the side face S of the dummy wiring R2 easily propagates in the direction returning to the EB opening 1b along the side face S of the dummy wiring R2. According to the present embodiment, since the dummy wiring R2 is disposed near the corner P2, it is possible to return the crack B having reached the dummy wiring R2 to the EB opening 1b. In other words, the dummy wiring R2 not only functions as a guide that changes the propagating direction of the crack B but also functions as a guide that returns the crack B to the EB opening 1b. The dummy wiring R2 can not only prevent the crack B originating from the corner P2 from propagating in the positive Y direction but also return the crack B to the EB opening 1b. Since the propagating direction of the crack B may also depend on randomness, it is possible that the crack B having reached the dummy wiring R2 does not return to the EB opening 1b.

The dummy wiring 11a including the portion R3 has an L shape in a plan view as illustrated in FIGS. 7 and 8C. Hereinafter, the dummy wiring 11a including the portion R3 is also referred to as a “dummy wiring R3”.

FIG. 8C illustrates a side face S of the dummy wiring R3 in the positive Y direction with bold lines. FIG. 8C also illustrates an angle θ that the side face S of the dummy wiring R3 forms in a plan view. The side face S of the dummy wiring R3 faces the corner P3 in a plan view as illustrated in FIG. 7. Specifically, the side face S of the dummy wiring R3 has a shape that forms a right angle (θ=90°) in a plan view and is recessed in the direction departing from the EB opening 1b. The shape of the side face S of the dummy wiring R3 is concave in the negative Y direction in a plan view.

In FIG. 7, the crack B originating from the starting point A at the corner P3 reaches the side face S of the dummy wiring R3 and returns to the EB opening 1b along the side face S of the dummy wiring R3 and the side face of the linear portion D4. Similarly to the dummy wiring R2, the dummy wiring R3 can not only prevent the crack B originating from the corner P3 from propagating in the negative Y direction but also return the crack B to the EB opening 1b. Moreover, since the side face S of the dummy wiring R3 has a shape that forms a right angle, not an arc, in a plan view, the dummy wiring R3 can further prevent broadening of the crack B than the dummy wiring R2. Since the propagating direction of the crack B may also depend on randomness, it is possible that the crack B having reached the dummy wiring R3 does not return to the EB opening 1b.

The dummy wiring 11a including the portion R4 has a V shape in a plan view as illustrated in FIGS. 7 and 8D. Hereinafter, the dummy wiring 11a including the portion R4 is also referred to as a “dummy wiring R4”.

FIG. 8D illustrates a side face S of the dummy wiring R4 in the negative X direction with bold lines. FIG. 8D also illustrates an angle θ that the side face S of the dummy wiring R4 forms in a plan view. The side face S of the dummy wiring R4 faces the corner P4 in a plan view as illustrated in FIG. 7. Specifically, the side face S of the dummy wiring R4 has a shape that forms an acute angle (θ<90°) in a plan view and is recessed in the direction departing from the EB opening 1b. The shape of the side face S of the dummy wiring R4 is concave in the positive X direction in a plan view.

In FIG. 7, the crack B originating from the starting point A at the corner P4 reaches the side face S of the dummy wiring R4 and returns to the EB opening 1b along the side face S of the dummy wiring R4. Similarly to the dummy wirings R2 and R3, the dummy wiring R4 can not only prevent the crack B originating from the corner P3 from propagating in the negative Y direction but also return the cracks B to the EB opening 1b. Moreover, since the side face S of the dummy wiring R4 has a shape that forms an acute angle, not an arc nor a right angle, in a plan view, the dummy wiring R4 can further prevent broadening of the crack B than the dummy wirings R2 and R3. Since the propagating direction of the crack B may depend on randomness, it is possible that the crack B having reached the dummy wiring R4 does not return to the EB opening 1b.

In FIG. 7, the four dummy wirings R1 to R4 disposed near one EB opening 1b have shapes different from one another. However, two or more of the dummy wirings R1 to R4 may have the same shape. In FIG. 7, the dummy wirings R1 to R4 having shapes different from one another are illustrated as examples for describing various examples of the shapes of the dummy wirings R1 to R4.

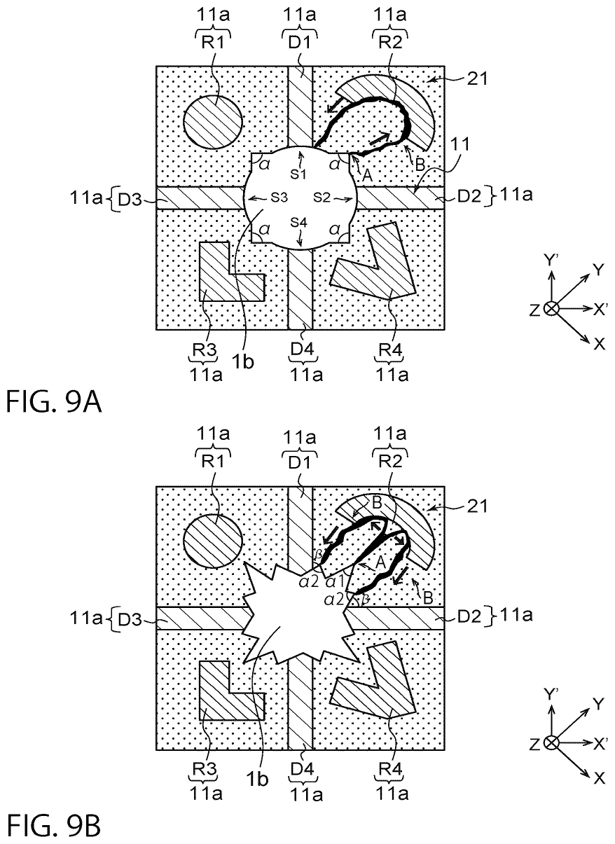

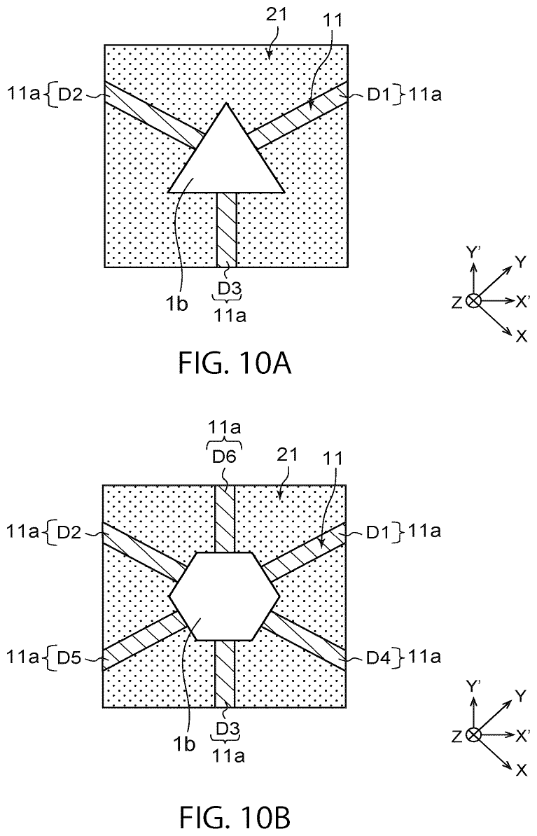

The shapes of the EB openings 1b and the dummy wirings R1 to R4 of the present embodiment may have height dependency (Z-directional dependency). For example, such height dependency is observed in a case where the side faces of the EB openings 1b and the dummy wirings R1 to R4 are tapered. In this case, the shapes of the EB opening 1b and the dummy wirings R1 to R4 illustrated in FIG. 7 may be defined at a predetermined XY section of the semiconductor device of the present embodiment. This is the same for FIGS. 9 and 10 to be described later.

Semiconductor devices of first to fourth modifications of the first embodiment will be described below with reference to FIGS. 9 and 10.

FIGS. 9A and 9B are plan views illustrating EB openings 1b of the first and second modifications of the first embodiment. FIGS. 9A and 9B are plan views corresponding to FIG. 7.

FIG. 9A illustrates the wiring layer 11, the resin layer 21, and an EB opening 1b of the first modification. FIG. 9A illustrates the linear portions D1 to D4 and the dummy wirings R1 to R4 but omits illustration of the planar portions C1 to C4.

Each EB opening 1b of the present modification has a planar shape of a circle provided with four corners (protrusion portions). Each corner has a shape that forms an angle α in a plan view. The angle α may be smaller than 90° (acute angle), larger than 90° (obtuse angle), or equal to 90° (right angle) but is desirably equal to or smaller than 90°. FIG. 9A illustrates a corner provided between the linear portions D1 and D3, a corner provided between the linear portions D1 and D2, a corner provided between the linear portions D3 and D4, and a corner provided between the linear portions D2 and D4. These corners are an example of the one or more protrusion portions and an example of the first protrusion portions.

FIG. 9A illustrates a crack B originating from a starting point A at a corner having the angle α. Similarly to the first embodiment, the present modification makes it possible to control the occurrence positions of the cracks B since the EB openings 1b are provided with corners.

FIG. 9B illustrates the wiring layer 11, the resin layer 21, and an EB openings 1b of the second modification. FIG. 9B illustrates the linear portions D1 to D4 and the dummy wirings R1 to R4 but omits illustration of the planar portions C1 to C4.

Each EB opening 1b of the present modification has a planar shape of a square provided with 12 corners (protrusion portions). Each corner has a shape that forms an angle α1 or an angle α2 in a plan view. The angles α1 and α2 may be smaller than 90° (acute angle), larger than 90° (obtuse angle), or equal to 90° (right angle) but is desirably equal to or smaller than 90°. In the present modification, the angle α2 is set to be larger than the angle α1 (α2>α1). In the region between the linear portions D1 and D3, one corner having the angle α1 is provided between two corners having the angle α2. This is the same for the region between the linear portions D1 and D2, the region between the linear portions D3 and D4, and the region between the linear portions D2 and D4. The corners having the angle α1 are an example of the one or more protrusion portions and an example of the first protrusion portions. The corners having the angle α2 are an example of the one or more protrusion portions and an example of second protrusion portions.

FIG. 9B illustrates a crack B originating from a starting point A at one corner having the angle α1. The crack B returns to two corners (end points) having the angle α2. Through discussions, it was found that the corners of the EB opening 1b are likely to serve as the starting point A and end points of the crack B. The reason is thought to be that large stress is likely to occur at corners. In addition, it was found that the corner having the angle α1 is likely to serve as the starting point A of the crack B and the corners having the angle α2 are likely to serve as the end points of the crack B. The reason is thought to be that stress is likely to be larger for a smaller angle. The present modification makes it possible to control the occurrence positions and end positions of the cracks B since the EB openings 1b are provided with these corners. Moreover, the present modification makes it possible to address two propagating directions of the cracks B as illustrated in FIG. 9B since one corner having the angle α1 is provided between two corners having the angle α2.

The occurrence positions and end positions of the cracks B may depended on randomness. For example, a corner having the angle α1 may sometimes serve as an end point of a crack B, and a corner having the angle α2 may sometimes serve as a starting point A of a crack B. Although the crack B illustrated in FIG. 9B originates from a starting point A and thereafter bifurcates into two branches and the two branches return to two end points, respectively, the crack B originating from the starting point A may return to only one of the two end points without bifurcating into branches. In this case, if the crack B propagates to left after originating from the starting point A, a corner with the angle α2 on the left side of the corner with the angle α1 can address the propagation of the crack B. If the crack B propagates to right after originating from the starting point A, a corner with the angle α2 on the right side of the corner with the angle α1 can address the propagation of the crack B.

FIG. 9B also illustrates, in the region between the linear portions D1 and D3, an angle βbetween the side face of the linear portion D1 and the side face of the EB opening 1b and between the side face of the linear portion D3 and the side face of the EB opening 1b. When the angle βis an acute angle, the boundary (hereinafter referred to as a “boundary 1”) between the side face of the linear portion D1 and the side face of the EB opening 1b and the boundary (hereinafter referred to as a “boundary 2”) between the side face of the linear portion D3 and the side face of the EB opening 1b are likely to serve as starting points A or end points of cracks B. Thus, the angle β is desirably set to be larger than the angles α1 and α2 (α1<α2<β) to prevent the boundaries 1 and 2 from serving as starting points A or end points of cracks B. Alternatively, the angle βmay be set to be larger than the angle α1 and smaller than the angle α2 (α1<β<α2) to prevent the boundaries 1 and 2 from serving as starting points A of cracks B. This is the same for the region between the linear portions D1 and D2, the region between the linear portions D3 and D4, and the region between the linear portions D2 and D4.

FIGS. 10A and 10B are plan views illustrating EB openings 1b of the third and fourth modifications of the first embodiment. FIGS. 10A and 10B are plan views corresponding to FIG. 7.

FIG. 10A illustrates an EB opening 1b of the third modification. Each EB opening 1b of the present modification has a triangular (for example, equilateral triangle) shape in a plan view. Accordingly, each EB opening 1b of the present modification has three side faces and three corners (protrusion portions). FIG. 10A also illustrates linear portions D1 to D3 (wirings 11a) extending from the side faces of the EB opening 1b. FIG. 10A omits illustration of the planar portions C1 to C3 of the wirings 11a and the dummy wirings 11a.

FIG. 10B illustrates an EB opening 1b of the fourth modification. Each EB opening 1b of the present modification has a hexagonal (for example, regular hexagon) shape in a plan view. Accordingly, each EB opening 1b of the present modification has six side faces and six corners (protrusion portions). FIG. 10B also illustrates linear portions D1 to D6 (wirings 11a) extending from the side faces of the EB opening 1b. FIG. 10B omits illustration of the planar portions C1 to C6 of the wirings 11a and the dummy wirings 11a.

As described above, the semiconductor device of the present embodiment includes the dummy wirings 11a disposed at positions facing the EB openings 1b. Thus, it is possible to prevent the cracks B from broadly propagating. Moreover, the present embodiment makes it possible to prevent, for example, fracture of the wiring layer 11 with the dummy wirings 11a. In other words, the present embodiment makes it possible to prevent defects due to the cracks B from occurring to the semiconductor device.

### Second Embodiment

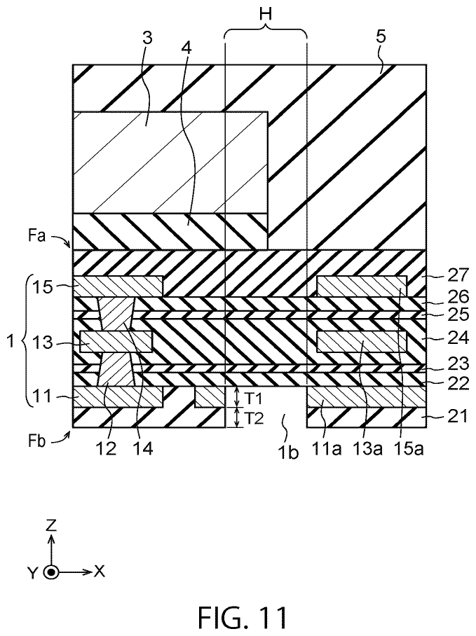

FIG. 11 is a cross-sectional view illustrating a structure of a semiconductor device of the second embodiment.

FIG. 11 corresponds to an enlarged view of FIG. 1. FIG. 11 illustrates a thickness T1 of the wiring layer 11 and a thickness T2 of the resin layer 21 at the lower face of the wiring layer 11. In the present embodiment, the thickness T2 is set to be smaller than the thickness T1 (T2<T1). As a result, the ratio of the volume of the wiring layer 11 to the total volume of the wiring layer 11 and the resin layer 21 is large and influence of the wiring layer 11 on cracks B is large. Accordingly, it is possible to facilitate propagation of the cracks B along the wirings 11a as illustrated in FIG. 7.

The relation between the thickness T1 of the wiring layer 11 and the thickness T2 of the resin layer 21 may hold between the wiring layer 15 and the resin layer 27 as well.

FIG. 11 also illustrates a region H overlapping an EB opening 1b in a plan view. Individual portions in the region H are positioned in the Z direction relative to the EB opening 1b. FIG. 11 also illustrates a plurality of wirings 11a in the wiring layer 11, a plurality of wirings 13a in the wiring layer 13, and a plurality of wirings 15a in the wiring layer 15. The wiring layers 11, 13, and 15 of the present embodiment do not include the wirings 11a, 13a, and 15a in the region H overlapping the EB opening 1b in a plan view. The reason is that cracks are likely to propagate in the Z direction from the EB opening 1b like a crack B9 illustrated in FIG. 2. The wirings 11a, 13a, and 15a are potentially fractured by such cracks if the wirings 11a, 13a, and 15a are disposed in the region H. The present embodiment makes it possible to prevent such fracture since the wirings 11a, 13a, and 15a are not disposed at a position overlapping the EB opening 1b in a plan view.

Such disposition of the EB opening 1b as illustrated in FIG. 11 are desirably applied also to the other EB openings 1b in the semiconductor device of the present embodiment and the EB openings 1a in the semiconductor device of the present embodiment.

The present embodiment makes it possible to further prevent defects due to cracks B from occurring to the semiconductor device. The semiconductor device of the present embodiment has a first property that the wiring layer 11 and the resin layer 21 have the relation of T2<T1 and a second property that the wiring layers 11, 13, and 15 do not include the wirings 11a, 13a, and 15a in the region H overlapping an EB opening 1b, but may have only one of the first and second properties instead.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor device comprising:
a substrate including one or more wiring layers, a first insulator provided on an upper face of a first wiring layer that is an uppermost layer among the one or more wiring layers, and a second insulator provided on a lower face of a second wiring layer that is a lowermost layer among the one or more wiring layers; and
a semiconductor chip provided on the substrate,
wherein the first or second wiring layer includes a first wiring and a second wiring that extend from an opening provided in the first or second insulator, and a third wiring that is provided at a position facing the opening between the first wiring and the second wiring.

2. The device of claim 1, wherein at least one of the first and second insulators is a solder resist layer.

3. The device of claim 1, wherein the third wiring has a side face facing the opening in a plan view, and the side face has a shape recessed in a direction departing from the opening.

4. The device of claim 3, wherein the side face has a curved shape in a plan view.

5. The device of claim 3, wherein the side face has a shape that forms an acute angle or a right angle in a plan view.

6. The device of claim 1, wherein the third wiring is electrically insulated from the first and second wirings.

7. The device of claim 1, wherein the third wiring is a dummy wiring that is not used to control the semiconductor device.

8. The device of claim 1, wherein the third wiring functions as a guide that changes a direction in which a crack occurring in the first or second insulator propagates from the opening.

9. The device of claim 1, wherein the opening has one or more protrusion portions protruding to the first or second insulator in a plan view.

10. The device of claim 9, wherein the one or more protrusion portions include a first protrusion portion provided between the first wiring and the second wiring in a plan view.

11. The device of claim 10, wherein the first protrusion portion has a shape that forms an acute angle or a right angle in a plan view.

12. The device of claim 10, wherein the one or more protrusion portions further include a second protrusion portion provided between the first wiring and the second wiring in a plan view.

13. The device of claim 12, wherein
the first protrusion portion has a shape that forms a first angle in a plan view, and
the second protrusion portion has a shape that forms a second angle different from the first angle in a plan view.

14. The device of claim 13, wherein the second angle is larger than the first angle.

15. The device of claim 9, wherein a crack in the first or second insulator is connected to any of the one or more protrusion portions.

16. The device of claim 12, wherein the crack in the first or second insulator is connected to the first protrusion portion and the second protrusion portion.

17. The device of claim 1, wherein the opening has a polygonal shape having three or more corners in a plan view.

18. The device of claim 1, wherein a thickness of the first insulator at the upper face of the first wiring layer is smaller than a thickness of the first wiring layer, or a thickness of the second insulator at the lower face of the second wiring layer is smaller than a thickness of the second wiring layer.

19. The device of claim 1, wherein each of the one or more wiring layers does not include a wiring provided at a position overlapping the opening in a plan view.

20. The device of claim 1, wherein
the first wiring is electrically connected to a first external connection pad, and
the second wiring is electrically connected to a second external connection pad.
